(19) United States
(12) Patent Application Publication
(10) Pub. No.: US 2025/0372529 A1
(43) Pub. Date: Dec. 4, 2025

(54) III-N SEMICONDUCTOR DEVICE WITH REDUCED SCRIBELINE VULNERABILITY

(71) Applicant: Texas Instruments Incorporated, Dallas, TX (US)

(72) Inventors: FUCHAO WANG, PLANO, TX (US); EBENEZER ESHUN, FRISCO`, TX (US); MARK L. JENSON, ALLEN, TX (US); WILLIAM DYER, GARLAND, TX (US); MANU J. PRAKUZHY, ALLEN, TX (US)

(21) Appl. No.: 18/731,131

(22) Filed: May 31, 2024

(51) Int. Cl. H01L 23/544; H01L 21/3105; H01L 21/311; H01L 21/762; H01L 29/20

(52) U.S. Cl. CPC H01L 23/544; H01L 21/31053; H01L 21/31111; H01L 21/76224; H10D 62/8503; H01L 2223/5446

(57) ABSTRACT

A semiconductor device, comprising, a semiconductor substrate, a III-N semiconductor layer over the semiconductor substrate, a dielectric layer along the III-N semiconductor layer, first and second trenches through the dielectric layer and the at least one III-N semiconductor layer, and a fill material filling at least a portion of each of the first and second trenches and having an upper surface aligned with an upper surface of the dielectric layer.

### CROSS-REFERENCE TO RELATED APPLICATION

Not Applicable.

### TECHNICAL AREA

Described examples relate to a semiconductor device and its fabrication, and more particularly, but not exclusively, to a III-N device, such as gallium nitride (GaN) or others (e.g., aluminum nitride, aluminum gallium nitride) with a reduced scribeline vulnerability structure and/or process.

### BACKGROUND

Semiconductor devices, such as integrated circuit (IC) devices, using III-N semiconductors such as GaN, are now providing designers, and IC users, with a practical and viable alternative to silicon metal-oxide-semiconductor field effect transistors (MOSFETS). GaN devices operate faster with high-speed switching capability in the MHz range, are smaller allowing higher power density systems, and are more efficient, allowing lower switching energy and reverse recovery losses.

In some examples, a number of GaN devices are formed in relation to a single semiconductor substrate, such as a semiconductor wafer, with each GaN device isolated from one or more other devices by a border area sometimes referred to as a scribeline. The scribeline does not include structure that is part of the final functionality of the GaN device, but may include identification information and/or provide an area in which cutting (dicing) is performed to separate each GaN device from the other(s). Both the structure of the cutting scribeline area and the manner of cutting can affect manufacturing processes and yield in the final result. For example, the structure may require various processing materials and/or steps, which can affect manufacturing complexity, time, and cost. As another example, some structures are less vulnerable to damage, such as crack propagation, when dicing is performed.

### SUMMARY

In an example, there is a semiconductor device, comprising, a semiconductor substrate, a III-N semiconductor layer over the semiconductor substrate, a dielectric layer along the III-N semiconductor layer, first and second trenches through the dielectric layer and the III-N semiconductor layer, and a fill material filling at least a portion of each of the first and second trenches and having an upper surface aligned with an upper surface of the dielectric layer.

Other aspects are also described and claimed.

### BRIEF DESCRIPTION OF THE DRAWINGS

FIGS. 1 through 6 are cross-section views representing successive fabrication stages and resultant structures of a semiconductor device.

FIGS. 7A and 7B are cross-section views representing two alternative process sequences following FIG. 6.

FIGS. 8 through 11A are cross-section views representing successive fabrication stages and resultant structures of a semiconductor device, following the alternative of either FIG. 7A or FIG. 7B.

FIG. 11B is a plan view corresponding to FIG. 11A.

FIG. 12 is a cross-section view representing additional steps following FIGS. 11A and 11B.

FIGS. 13 and 14 are alternative steps to FIGS. 2 and 3.

FIG. 15 is a flow diagram of an example method summarizing various of the steps for manufacturing the semiconductor device.

### DETAILED DESCRIPTION

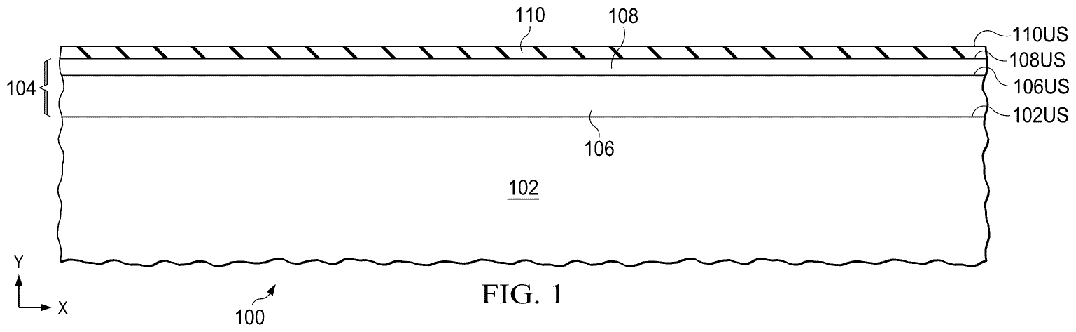

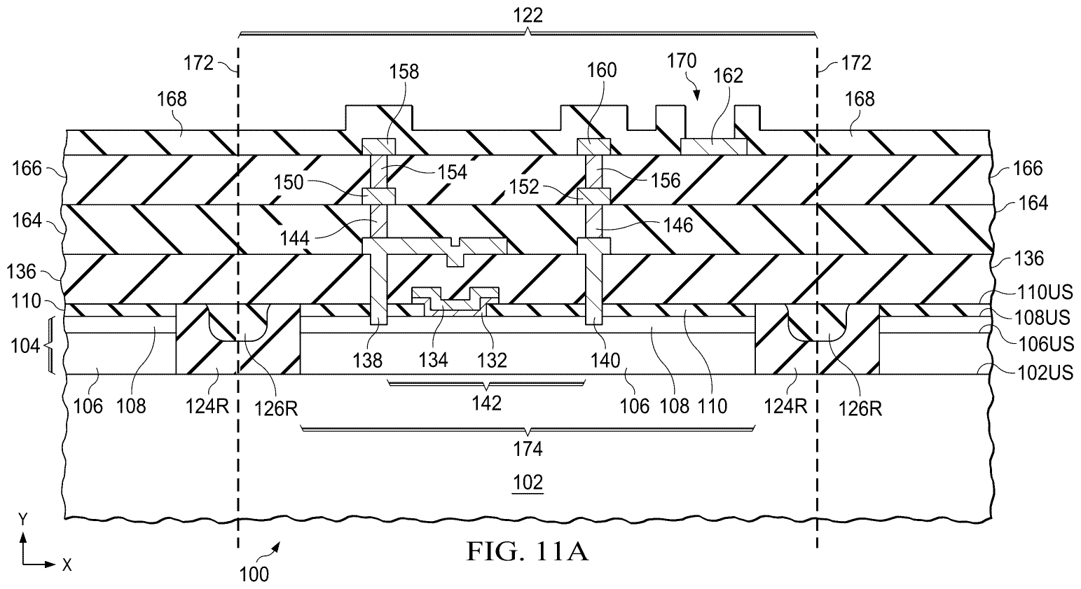

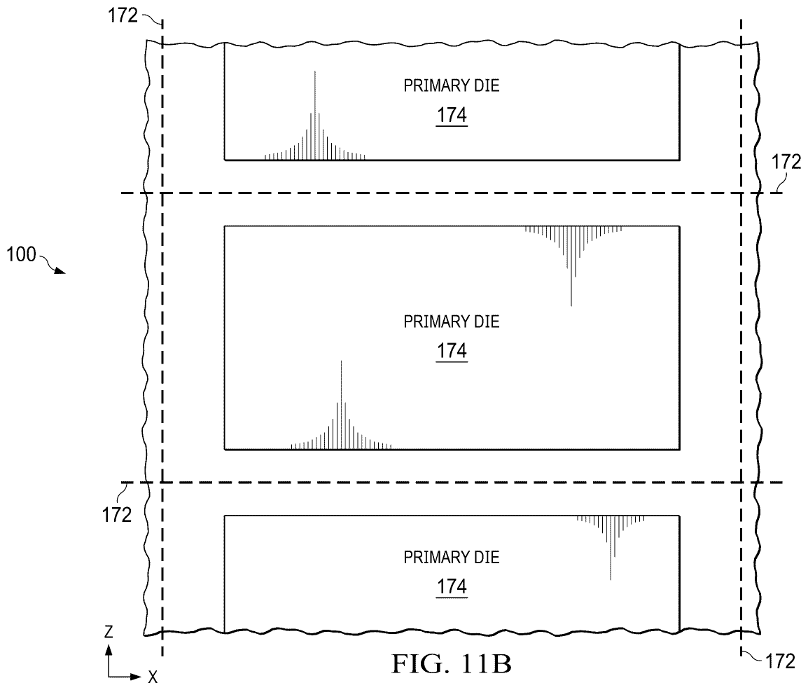

Examples are described with reference to the attached figures, which may not be drawn to scale. Several aspects are described with reference to example applications for illustration, in which like features correspond to like reference numbers. In FIG. 1 and various later figures, cross-sectional views are shown in an x-y (horizontal-vertical) plane but should be understood to also have features in the z-dimension, understood to be extending in a direction in and out of the illustrated image plane (for example, represented also in the x/z plan view in FIG. 11B). The directional references are for purposes of relative placement, but such terms are not intended to be restrictive as the device may be rotated in space and thereby change absolute, but not relative, references. Numerous specific details, relationships, and processes/methods are set forth to provide an understanding, but the scope is not necessarily limited by the illustrated ordering of acts or events, as some acts may occur in different orders and/or concurrently with other acts or events. Further, not all illustrated acts or events may be required to implement a process or methodology in accordance with one or more examples.

The examples relate to semiconductor device fabrication, and more particularly but not exclusively to a semiconductor device 100 that may be implemented as a III-N (e.g., a group-III nitride material such as GaN) field effect transistor (FET). The GaN FET may be formed at a same time and sharing certain process steps with other devices. This document provides examples that may improve on certain concepts, as detailed below. While such examples may be expected to provide one or more of various advantages, no particular result is a requirement unless explicitly recited in a particular claim.

FIG. 1 is a cross-section and partial view of the semiconductor device 100, for example a portion of an IC. The semiconductor device 100 includes a semiconductor substrate 102, for example as part of a silicon wafer. The wafer typically provides either a P-type or N-type semiconductor, and the semiconductor substrate 102 can represent a portion of the bulk wafer or a region (e.g., a well and/or buried layer and/or epitaxial layer) formed in connection with the wafer. The wafer typically includes multiple locations, each corresponding to a same or different IC on the wafer, so the illustration of FIG. 1 (and later figures) can be repeated in each wafer IC location as shown in FIG. 11B, where each such location is shown as a primary die. As detailed later, each such primary die may be separated from one or more others, by cutting in the y-dimension near the periphery areas shown in FIG. 1 and as detailed later in FIGS. 11A and 11B.

As now introduced with FIG. 1 and detailed in the remaining figures, a GaN device, which in the illustrated example is a GaN FET, is formed in connection with the substrate 102 and generally with a lateral (x/z plane) layout. In that regard, a III-N semiconductor layer stack 104 is formed along an upper surface 102US of the substrate 102. The III-N semiconductor layer stack 104 may include one or more III-N (e.g., gallium) materials, and by example is shown to include two layers (or sub-layers). A first layer 106 (or layer stack), for example implemented as a GaN layer 106 (sometimes referred to as a GaN buffer), is formed at least in part, aligned along the x/z plane provided by an upper surface 102US of the substrate 102. The GaN layer 106 may be formed by a sequence of vapor phase epitaxial processes, and it may have a thickness in a range from 1.2 μm to 7.0 μm, depending in part on the maximum operating potential of the GaN FET. A second layer 108, for example implemented as an aluminum gallium nitride (AlGaN) barrier layer 108, is formed along an upper surface 106US of the first (GaN) layer 106. The second layer 108 may have a thickness in a range from 5 nm to 30 nm. After the one or more III-N layers of the layer stack 104 are formed, a passivation layer 110, such as a dielectric layer (e.g., silicon nitride (SiN)), is formed along an upper surface 108US of the second layer 108. The passivation layer 110 may be formed by a low-pressure chemical vapor deposition (LPCVD) process, and with a thickness in a range from 20 nm to 200 nm. The passivation layer 110 also may be referred to as a first pre-metal dielectric (PMD) layer.

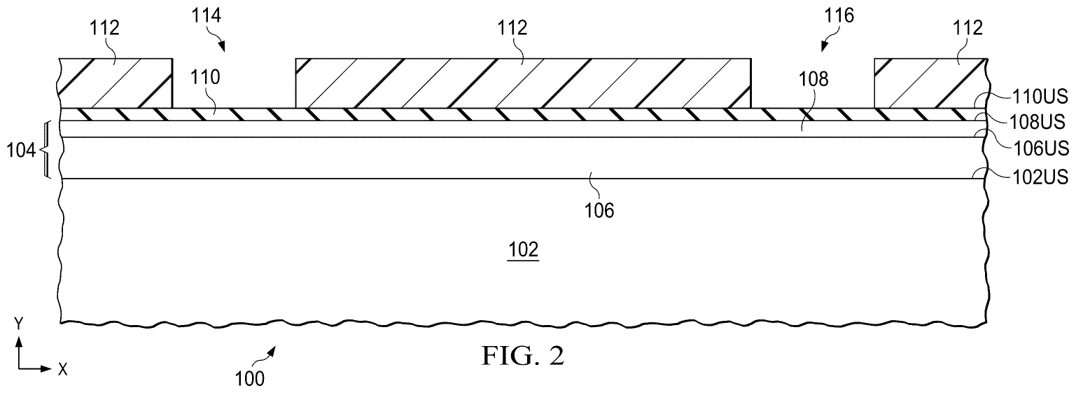

In FIG. 2, an etch mask (e.g., photoresist) layer is formed over the FIG. 1 structure and patterned to form etch mask portions 112. The etch mask may include a material that is resistant to further etch processes, with the etch-resistant material including, for example, silicon dioxide (SiO₂) or silicon nitride (Si₃N₄). Open areas 114 and 116 are provided between the etch mask portions 112, in the areas where respective portions of an upper surface 110US of a passivation layer 110 are exposed. For example, the width of each of the open areas 114 and 116, in the x-dimension, may be in a range from 50 μm to 100 μm.

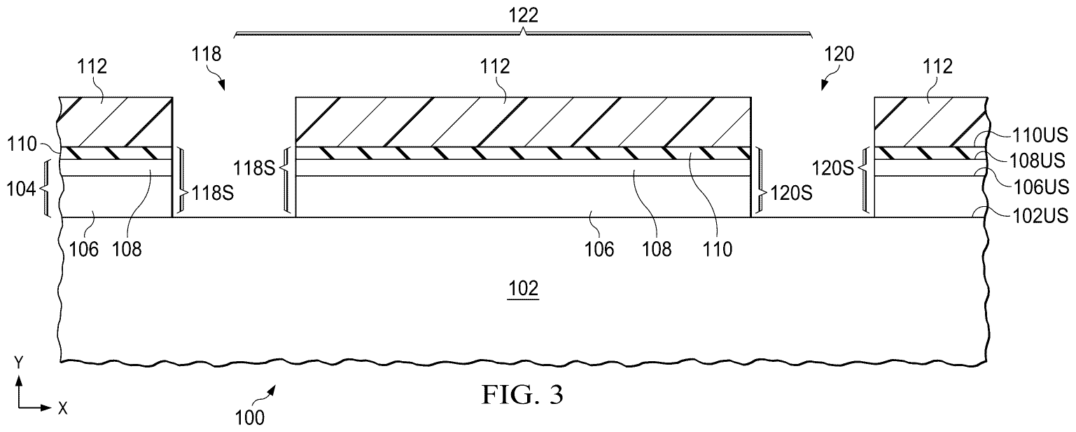

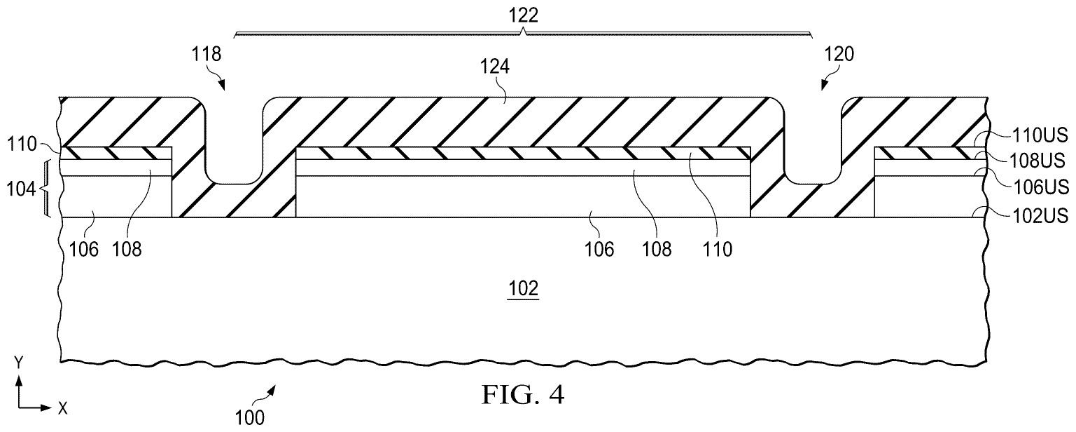

In FIG. 3, an etch is performed through the FIG. 2 open areas 114 and 116 and down (in the y-dimension) to the upper surface 102US of the substrate 102, thereby forming respective trenches 118 and 120. For example, the etch may be performed using reactive ion etching. The resulting trench 118 has y-dimension sidewalls 118S that include layers from the III-N semiconductor layer stack 104 and the passivation layer 110, and similarly the trench 120 has y-dimension sidewalls 120S that also include layers from the III-N semiconductor layer stack 104 and the passivation layer 110. Each of the trenches 118 and 120 also has a bottom portion provided by the upper surface 102US of the substrate 102. Accordingly, each of the trenches 118 and 120 has a same total depth in the y-dimension, ranging from 1.0 μm to 8.0 μm, and a width in the x-dimension as defined by the above-described width of the open areas 114 and 116. A device area 122 (which may also be referred to as an active area) is generally provided between the trenches 118 and 120, in which one or more devices (e.g., GaN transistor) may be formed, so as to create in total a primary die (see FIG. 11B). FIG. 3 also continues to illustrate the etch mask portions 112 that remain following the etch that forms the trenches 118 and 120, and such portions are subsequently removed (e.g., with a cleaning agent or other suitable etchant) to form portions of the structure shown in FIG. 4.

In FIG. 4, a first trench fill layer 124 is formed atop the FIG. 3 structure, after the etch mask portions 112 are removed. In an example, the first trench fill layer 124 is SiO₂, which may be formed by plasma enhanced chemical vapor deposition (PECVD). Also in an example, the first trench fill layer 124 does not include nitrogen. The first trench fill layer 124 may have a thickness in the y-dimension, ranging from 0.5 μm to 7.0 μm, depending on trench depth. Particularly, this thickness may be chosen to be less than the depth of the trenches 118 and 120, which recall from above is indicated to range from 1.0 μm to 8.0 μm. For example, the thickness may be between 50% and 90% of the trench depth. In a numeric example, where the trench depth is 7 μm, then the trench fill layer 124 may have a thickness of 4 μm. Accordingly, the first trench fill layer 124 only partially fills each of the trenches 118 and 120 relative to the upper planar surface for each trench (along the x-dimension), which corresponds to the upper surface 110US of the passivation layer 110.

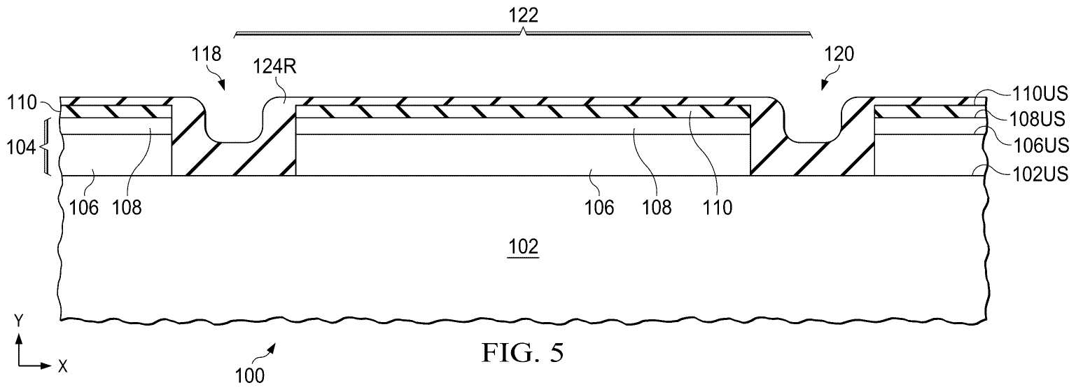

In FIG. 5, the FIG. 4 first trench fill layer 124 is planarized downward in the y-dimension and to form an x/z plane, so that FIG. 5 depicts the post-planarized portion of layer 124 as a remaining layer 124R. The planarization may be performed, for example, using an oxide chemical mechanical polish (CMP). The amount of layer 124 material removed by the FIG. 5 planarization is selected so that a portion of the remaining layer 124R remains along the upper surface 110US. For example, the FIG. 5 planarization may remove a percent of the thickness of the FIG. 4 first trench fill layer 124, with the removal being in a range of 90% or more of that thickness, but less than 100%.

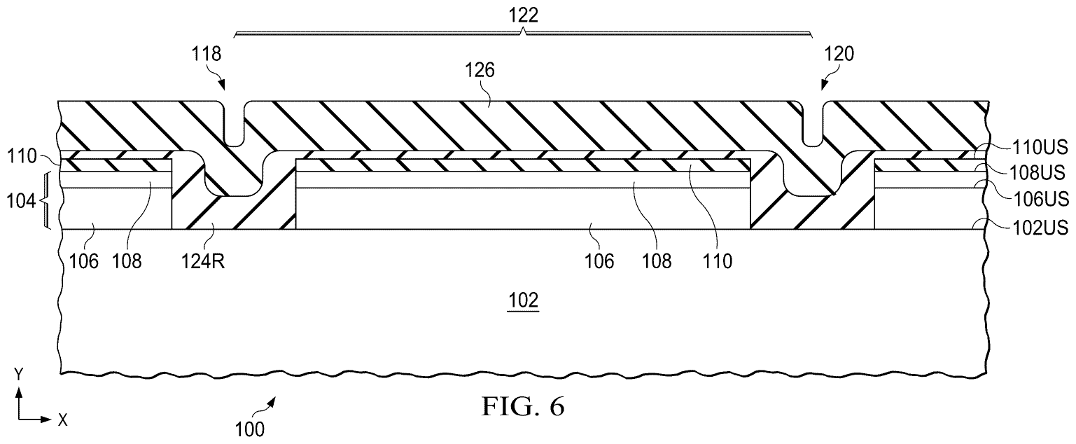

In FIG. 6, a second trench fill layer 126 is formed atop the FIG. 5 structure. In an example, the second trench fill layer 126 is the same material as the first trench fill layer 124, such as SiO₂. Also in an example, the second trench fill layer 126 does not include nitrogen. Accordingly, a same process may be used for forming both the first and second trench fill layers 124 and 126 (e.g., PECVD). The second trench fill layer 124 may have a thickness in the y-dimension so as to fill any remaining open area in each of the trenches 118 and 120, relative to the plane (x/z plane) along the upper surface 110US. For example, the second trench fill layer 124 thickness may range from 1.0 μm to 4.0 μm.

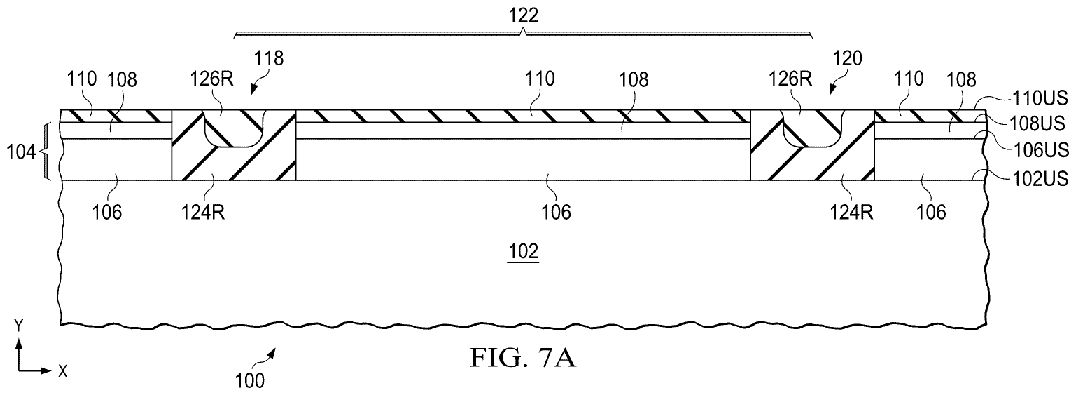

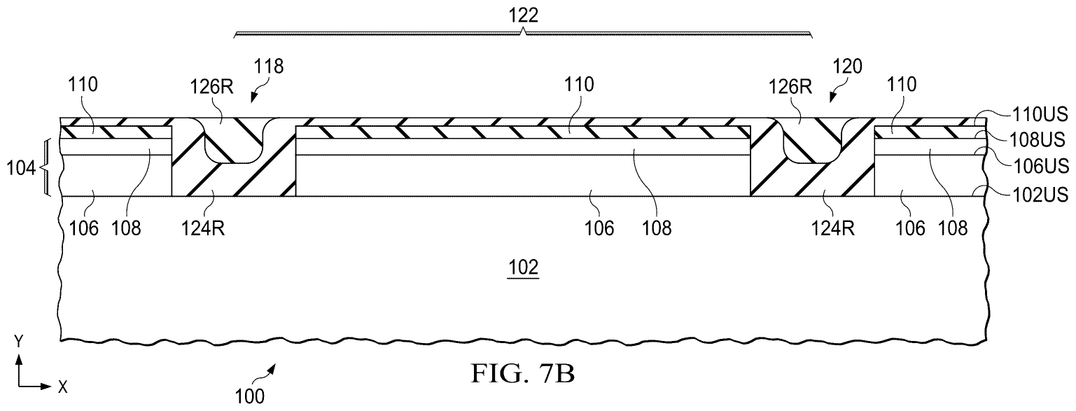

FIG. 7A illustrates a first alternative of removing at least some of excess trench fill materials above the passivation layer 110 of the FIG. 6 structure. In FIG. 7A, the first and second trench fill layers 124 and 126 are planarized downward in the y-dimension until the upper surface 110US is reached. The planarization may be achieved using a CMP process. Accordingly, FIG. 7A shows remaining portions 126R of the second trench fill layer 126, above corresponding portions of the remaining layer 124R in each of the trenches 118 and 120.

FIG. 7B illustrates a second alternative of removing at least some of excess trench fill materials above the passivation layer 110 of the FIG. 6 structure. In FIG. 7B, the first and second trench fill layers 124 and 126 are planarized (e.g., CMP) downward in the y-dimension and to form an x/z plane, with the planarization process stopping before reaching the upper surface 110US. Accordingly, FIG. 7B also shows remaining portions 126R of the second trench fill layer 126 above corresponding portions of the remaining layer 124R in each of the trenches 118 and 120 (and above the upper surface 110US if the planarization process stops to leave a portion of the second trench fill layer 126 outside the trenches 118 and 120 (not shown in FIG. 7B)), but in addition a portion of the first layer 124R, as a remaining portion of the first fill layer 124, also remains above the upper surface 110US. Such an approach may reduce the chance of damaging the passivation layer 110 from the planarization process, as such damage could ultimately affect performance of the device being formed in the device area 122. Further, once the planarization is achieved mechanically to the level illustrated in FIG. 7B, an additional process, for example a wet oxide etch process, may be used for removing the excess trench fill materials above the passivation layer 110 in the y-dimension until the upper surface 110US is reached (e.g., exposed). In this manner, the planarization process (e.g., CMP) used from the prior removal of the first and second trench fill layers 124 and 126 does not impact that upper surface 110US.

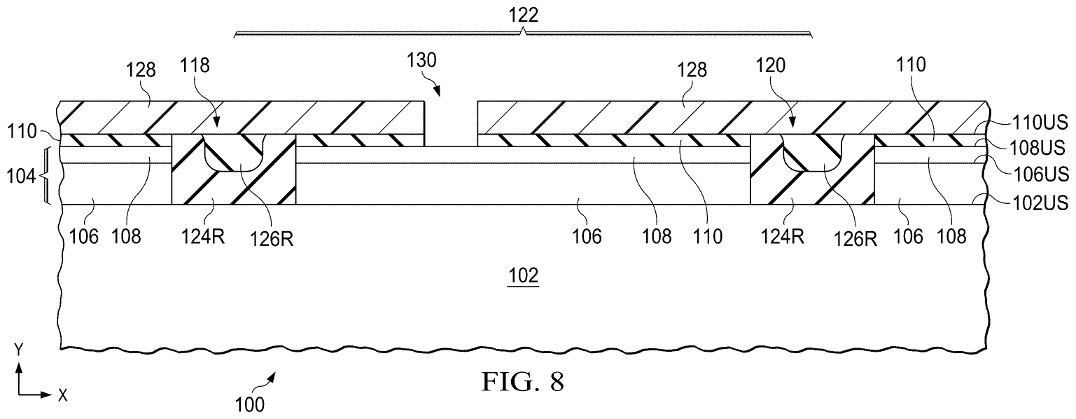

FIG. 8 illustrates additional structure/steps following FIG. 7A, although a comparable approach may be implemented following FIG. 7B. In FIG. 8, an etch mask (e.g., photoresist) layer is formed over the structure and patterned and etched to form etch mask portions 128. The etch mask may include a material resistant to further etch processes, such as SiO₂ or Si₃N₄. An open area 130 is provided between the etch mask portions 128, through which the etch is applied through the passivation layer 110 and down to the upper surface 108US. The width of the open area 130, in the x-dimension, may be in a range from 0.5 μm to 2.0 μm.

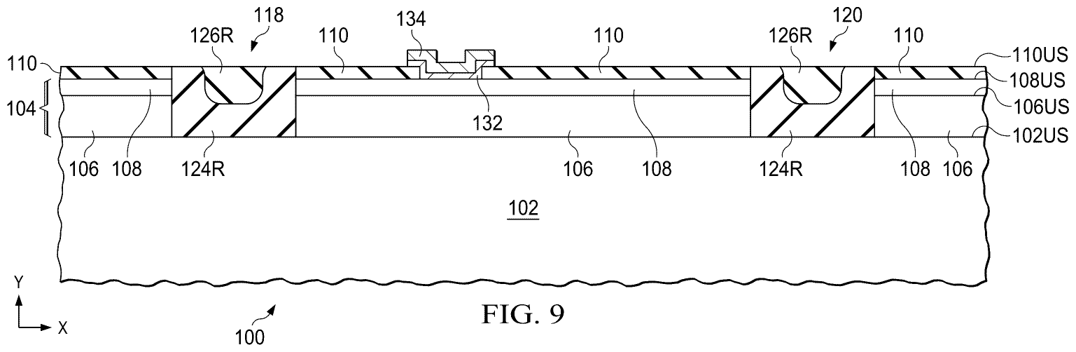

In FIG. 9, an additional gate dielectric 132 and a gate terminal 134, both for a GaN FET, are formed and aligned relative to the FIG. 8 open area 130. In an example, these two structures are formed by removing the FIG. 8 mask portions 128, forming a dielectric layer (e.g., silicon nitride) over the exposed surface, forming a metal layer (e.g., titanium, titanium nitride, titanium tungsten, tungsten, aluminum, nickel, or gold) over the just-formed dielectric layer, and then patterning and etching those two layers. The resultant gate dielectric 132 and gate terminal 134 are generally conformal and positioned relative to what was the FIG. 8 open area 130. In some examples, the gate dielectric 132 includes a same material as the passivation layer 110.

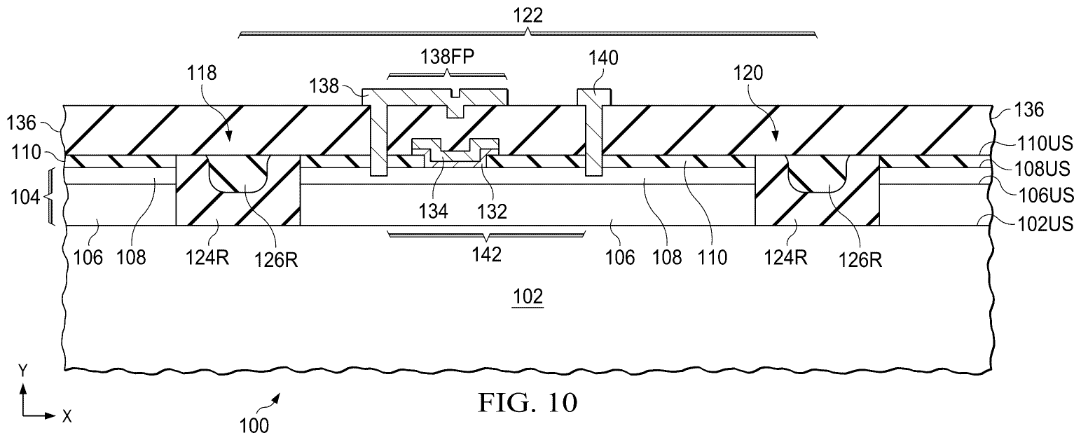

In FIG. 10, an additional dielectric layer, such as a second PMD layer 136, is formed and planarized (e.g., using CMP process). The second PMD layer 136 may be conformal, and it may include SiN or SiO₂. Alternatively, the second PMD layer 136 may include plural layers, for example, a first layer of SiN followed by a second layer of SiO₂. The second PMD layer 136 (or its layers) may be formed by PECVD or by a high density plasma (HDP) deposition, for example to use relatively low temperature (e.g., at or below 300° C.) to avoid degradation to the conductive materials (e.g., the gate terminal 134). The second PMD layer 136 as shown in FIG. 10 may have a thickness in a range from 0.1 μm to 0.5 μm, and it may provide dielectric isolation between the GaN FET gate terminal 134 and the source terminal 138 (described below).

Also in FIG. 10, after the second PMD layer 136 is formed, a first and second via (shown already filled with conductive material in FIG. 10) are formed on opposing lateral (x-dimension) sides of the gate terminal 134. The first and second vias are formed through the second PMD layer 136 and the passivation layer 110, stopping at or extending through the upper surface 108US and into the second layer 108. Thereafter, the vias are filled with conductive material such as metal, for example by applying a metal layer (e.g., of the same metal as the gate terminal 134) over the planarized surface of the second PMD layer 136 and the first and second via, and then patterning and etching the metal layer to form two conductive terminals of the GaN FET. Particularly, a first of the two conductive terminals includes a source terminal 138, formed in a first direction laterally away (in the x-dimension) from the gate terminal 134 and having a portion extending through both the passivation layer 110 and the second PMD layer 110 and contacting or extending into the second layer 108. The source terminal 138 also includes a source field plate 138FP, which extends laterally in the x-dimension from the source terminal 138 and over the gate terminal 134 and is separated from that gate terminal 128—e.g., by a dielectric layer, such as the second PMD layer 136. A second of the two conductive terminals includes a drain terminal 140, formed in a second direction, opposite the first direction, laterally away from the gate terminal 134 and having a portion extending through both the passivation layer 110 and the second PMD layer 110 and contacting or extending into the second layer 108. In operation, the GaN FET does not have P/N junction operation as in the case of MOSFETs, but instead the heterojunction between the second layer 108 and the first layer 106 forms a two-dimensional electron gas (2DEG) in a portion of the first layer 106 proximate the second layer 108, at least in a region 142 between the source terminal 138 and the drain terminal 140. The 2DEG has very high charge carrier density and mobility, in which current flows between the source and drain terminals 138, 140 under the proper electrical conditions.

FIG. 11A illustrates a cross-sectional view, and FIG. 11B illustrates a plan view, of the FIG. 10 structure following additional structure-forming steps. The additional structure may be of numerous variations, so FIG. 11A illustrates merely a single example of additional dielectric layers (sometimes referred to as intermetal dielectric layers (IMD)) and additional metal layers with corresponding metal vias. Specifically, FIG. 11A illustrates a metal-2 portion including metal vias 144 and 146 in contact with respective second metal layer structures 150 and 152 and also respectively with already-formed source terminal 138 and drain terminal 140. Similarly, FIG. 11A illustrates a metal-3 portion including metal vias 154 and 156 in contact with respective third metal layer structures 158 and 160 (and respectively to second metal layer structures 150 and 152). The metal-3 portion also includes a conductor pad 162. An IMD layer 164 is above the planarized second PMD layer 136, and an IMD layer 166 is above the IMD layer 164. A conformal layer, such as an oxide (or phosphorous doped oxide (PO oxide)) layer 168, may be formed over the IMD layer 166 and have one or more open areas 170 formed so that electrical contact may be made to metal-3 structures, for example as shown by an open area 170 above the contact pad 162.

FIGS. 11A and 11B also illustrate a number of scribelines 172, shown as y-dimension dashed lines at the edges of the device area 122 in FIG. 11A, and as both x- and z-dimension dashed lines between the primary die 174 in FIG. 11B. The scribelines 172 are lines along which cuts are made to separate each primary die 174 (or device area 122) from one or more others. Cuts are made along the scribelines 172, for example using a dicing saw which may include a diamond or other abrasive blade. As visible from the FIG. 11A perspective, such cuts pass, in order of contact, first through the oxide layer 168, next through the IMD or PMD layers 166, 164, and 136, then through the remaining portions 126R, the remaining layer 124R, and the substrate 102.

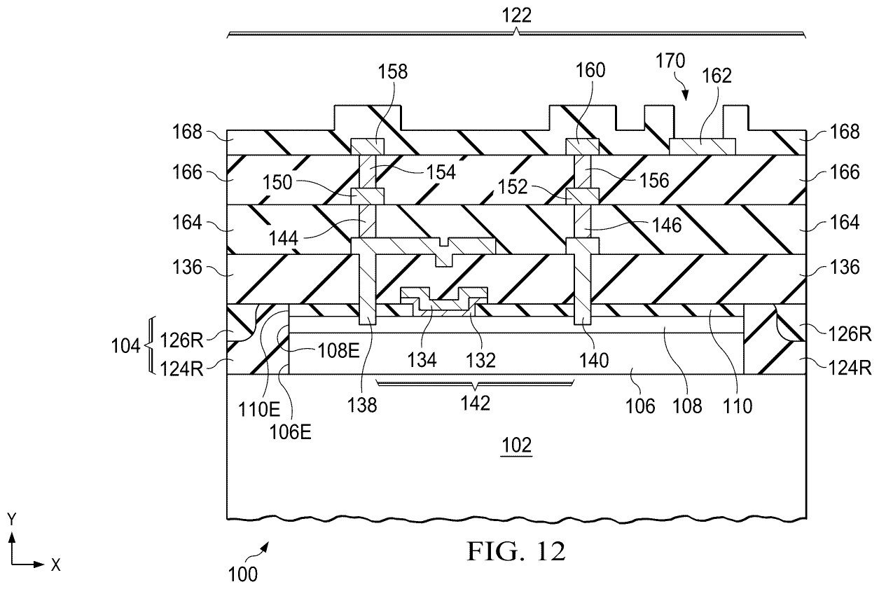

FIG. 12 illustrates the FIG. 11A structure after the dicing cuts are complete along the scribelines 172, thereby illustrating a device (or collection of devices) in a single device area 122 once separated from any adjacent (device) on the wafer. Note that the remaining layer 124R and the remaining portions 126R together provide fill material in each area of what was formerly the trenches 118 and 120 (see FIG. 3), and where the scribelines 172 were used as the locational target for dicing. Further, of that fill material, the remaining layer 124R abuts three different vertical (y-dimension) and respective edges, namely, an edge 110E of the passivation layer 110, an edge 108E of the second layer 108, and an edge 106E of the first layer 106. In this regard, the remaining layer 124R provides protection to such layers during the dicing described in connection with FIGS. 11A and 11B, for example by reducing the opportunity for cracking or crack propagation. Further, such protective fill material is formed prior to the formation of one or more of the second PMD layer 136, the IMD layer 166, and the IMD layer 164, thereby reducing or eliminating complexities as compared to an alternative where deeper trenches would be required to be formed, for providing such protection in a scribe area, after the formation of one or more of those layers. Mitigating such complexities may improve any one or more of reducing thickness and considerations and/or byproducts of thick photolithography processes, reducing the chance of electrical arcing that could occur to internal metal structures during deep trench etching, less complex alignment errors, fewer steps and/or time required for additional steps, reducing post etch cleaning considerations, elimination of issues arising from higher (in the y-dimension) layers extending down to the trench areas, and so forth.

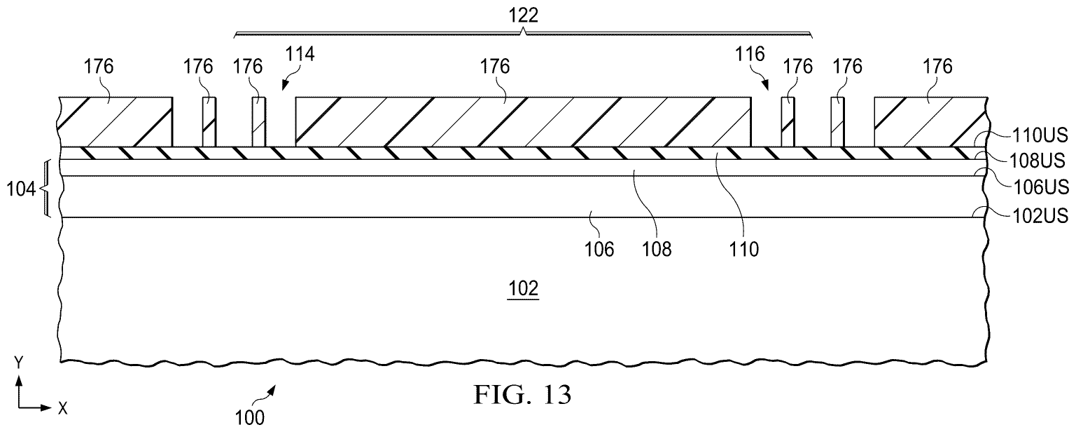

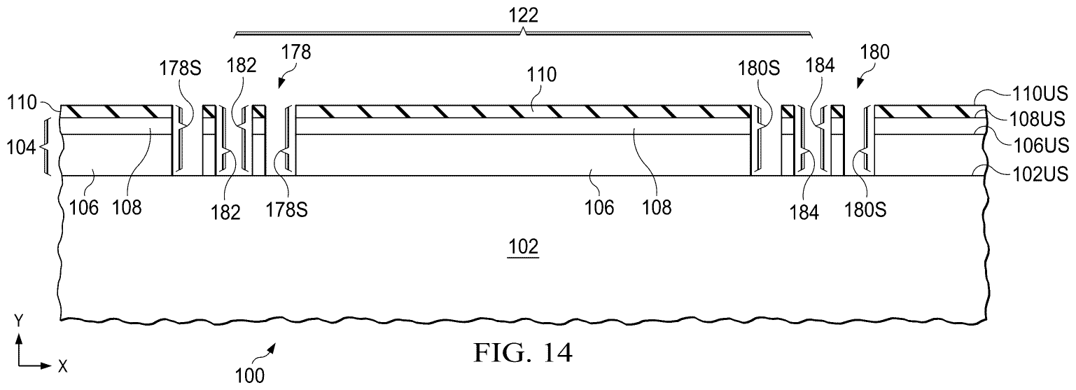

FIG. 13 illustrates an alternative masking approach to FIG. 2, for forming dummy structures (or dummy stacks) within the trenches 178 and 180 as further described and shown in connection with FIG. 14. In FIG. 13, an etch mask (e.g., photoresist) layer is formed over the FIG. 1 structure and patterned and etched to form etch mask portions 176. The etch mask may include SiO₂ or Si₃N₄. In comparing FIGS. 2 and 13, the FIG. 13 mask portions 176 cover the same area as the FIG. 2 mask portions 112 laterally (in the x-dimension) away from the open areas 114 and 116, while in FIG. 13 one or more additional mask portions 176 are formed within the open areas 114 and 116. As shown below, each mask portion 176 within the open areas 114 and 116 ultimately serves to allow for a corresponding dummy stack, so the width of the open areas 114 and 116 and number and dimensions of each mask portion 176 therein are selected accordingly. Further, in general the wider the open areas 114 and 116, the more mask portions 176 (and later, corresponding dummy stacks) are formed therein, for example filling at least 50% of the width of each open area 114, 116 with one or more mask portions 176.

In FIG. 14, an etch is performed through the FIG. 13 open areas 114 and 116 and down (in the y-dimension) to the upper surface 102US of the substrate 102, thereby forming respective trenches 178 and 180, and thereafter the mask portions 176 are removed. The etch may be performed using reactive ion etching and results in the trench 178 having y-dimension sidewalls 178S that include layers from the III-N semiconductor layer 104 and the passivation layer 110, and similarly the trench 180 has y-dimension sidewalls 180S that also include layers from the III-N semiconductor layer 104 and the passivation layer 110. Each of the trenches 178 and 180 also has plural bottom portions provided by the upper surface 102US of the substrate 102. Additionally, between the respective sidewalls 178S are multiple (e.g., two) dummy stacks 182, and between the respective sidewalls 180S are multiple dummy stacks 184. By way of example, each dummy stack 182 or 184 may have a width in the x-dimension, ranging from 1.0 μm to 5.0 μm.

Each dummy stack 182 and 184 includes the same layers in the device area 122, namely, a lowermost portion of the first layer 106, atop which is a portion of the second layer 108, atop which is a portion of the passivation layer 110. Further, each dummy stack 182, 184 may have a same plan-view shape, such as square, rectangular, circular, cross, bar, and so forth. The term dummy stack is to identify that the stack is a structure that has non-operational purpose and does not function as part of the device in the device area 122. In the illustrated example, the dummy structures 182 and 184 are included in the respective trenches 178 and 180 to improve planarization of the fill material to be formed in those trenches. Particularly, after the FIG. 14 structure is formed, each of the trenches 178 and 180 is filled with a fill material, using for example any of the processes described above for filling the trenches 118 and 120. For example, either a single or dual fill layering may be used, as may etching steps that include one or more etches down to the passivation layer 110. By adding the dummy structures 182 and 184, then the lateral opening (x-dimension) between neighboring structures within each trench is less than the total width of the trench 178 or 180 in which a dummy structure(s) is located. As a result, when a fill material layer or layers is formed along the entire FIG. 14 structure, the thickness of such a layer(s) may be less than as shown in FIGS. 4-7B, due to the narrower lateral area to be filled. Further, the use of a thinner fill layer(s) as may be used with the FIG. 14 structure provides less opportunity for concavity, sometimes referred to as dishing, along the surface of the fill material layer(s).

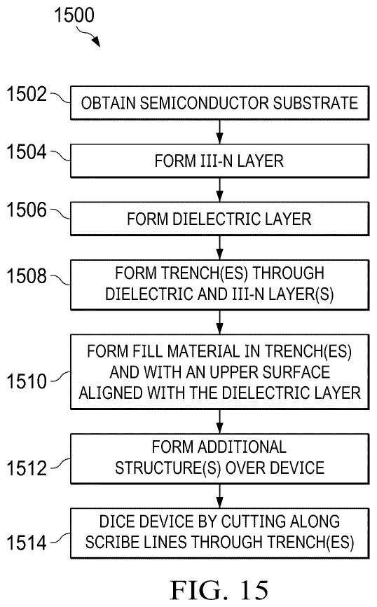

FIG. 15 is a flow diagram of an example method 1500 summarizing various of the above-described steps for manufacturing the semiconductor device 100, for example as shown in FIGS. 1-14. The method 1500 begins in a step 1502, in which the FIG. 1 semiconductor substrate 102 is obtained. The semiconductor substrate 102, at this stage, may be a bare wafer or may have one or more semiconductor features already formed on it. The semiconductor substrate 102 also includes one or more device areas, or one or more electrical structures adjacent to such an area, in which it is desirable to form devices including silicon or III-N materials, for example such as a transistor. Next, in a step 1504, a III-N layer 106, 108 is formed over the semiconductor substrate 102, where the III-N layer may include one or more III-N sub-layers (GaN layer, AlGaN layer, and so forth). Next, in a step 1506, a passivation (dielectric) layer 110 is formed. Next, in a step 1508, first and second trenches 118 and 120, or 178 and 180, are formed through the dielectric layer 110 and the III-N layer 104, for example to expose a respective surface, in each of those trenches, of the semiconductor substrate 102. Next, in a step 1510, a fill material is formed in the trench(es) and to align with an upper surface of the dielectric layer 110. For example, the fill material may include one or more of the first trench fill layer 124 and the second trench fill layer 126, as may be planarized for example using one or more steps as described above, and with or without the combination of a dummy structure(s) within the trench(es). Next, in a step 1512, one or more additional structures or layers may be formed above the prior structures. These structures may include one or more metal layers 150 and 152, and 158 and 160, and one or more dielectric layers 136, 164, and 166, among others. Lastly, in a step 1514, the active area is diced by cutting along scribelines 172 vertically through the earlier-formed trench(es).

From the above, one skilled in the art should appreciate that examples are provided for semiconductor fabrication, for example with respect to an IC that includes a semiconductor substrate, a III-N layer overlying the semiconductor substrate, a dielectric layer overlying the III-N layer, and filled trenches through the dielectric and III-N layers. Such examples may provide various benefits, some of which are described above and including still others. Still additional modifications are possible in the described examples, and other examples are possible, within the scope of the following claims.

What is claimed is:

1. A semiconductor device, comprising:
a semiconductor substrate;
a III-N semiconductor layer over the semiconductor substrate;
a dielectric layer along the III-N semiconductor layer;
first and second trenches through the dielectric layer and the III-N semiconductor layer; and
a fill material filling at least a portion of each of the first and second trenches and having an upper surface aligned with an upper surface of the dielectric layer.

2. The semiconductor device of claim 1, wherein the III-N semiconductor layer comprises a gallium nitride sub-layer and an aluminum gallium nitride sub-layer.

3. The semiconductor device of claim 1 wherein the fill material comprises silicon dioxide, exclusive of nitrogen.

4. The semiconductor device of claim 1 wherein the fill material comprises silicon dioxide.

5. The semiconductor device of claim 1 wherein the fill material abuts an edge of the dielectric layer.

6. The semiconductor device of claim 1 wherein an edge of the dielectric layer is aligned with an edge of the III-N semiconductor layer.

7. The semiconductor device of claim 1, wherein the fill material comprises:
a first silicon dioxide portion abutting a respective edge of the dielectric layer and the at least one III-N semiconductor layer; and
a layer stack abutting a respective edge of the first silicon dioxide portion.

8. The semiconductor device of claim 7 wherein the layer stack comprises a first portion of the III-N semiconductor layer and a second portion of the dielectric layer.

9. The semiconductor device of claim 1 having a device area between the first and second trenches, and further comprising a circuit device in the device area.

10. The semiconductor device of claim 9 wherein the circuit device comprises a III-N transistor.

11. The semiconductor device of claim 10 wherein the III-N transistor includes a gate dielectric of a same material as the dielectric layer.

12. A semiconductor device, comprising:
a semiconductor substrate;
a III-N semiconductor layer over the semiconductor substrate;
a first dielectric layer along the III-N semiconductor layer;
first and second trenches through the first dielectric layer and the at least one III-N semiconductor layer;
a transistor source in contact with the III-N semiconductor layer;
a transistor drain in contact with the III-N semiconductor layer;
a transistor gate between the transistor source and the transistor drain; and
a fill material filling at least a portion of each of the first and second trenches and having an upper surface aligned with an upper surface of the first dielectric layer.

13. The semiconductor device of claim 12 and further comprising a second dielectric layer between the transistor gate and the III-N semiconductor layer.

14. The semiconductor device of claim 13 wherein the second dielectric layer is of a same material as the first dielectric layer.

15. A method of forming a semiconductor device, comprising:
forming a III-N semiconductor layer over a semiconductor substrate;
forming a dielectric layer along the III-N semiconductor layer;
forming first and second trenches through the dielectric layer and the III-N semiconductor layer; and
filling at least a portion of each of the first and second trenches with a fill material to have an upper surface aligned with an upper surface of the dielectric layer.

16. The method of claim 15, wherein the filling comprises:
forming a first fill material layer within along sidewalls and a bottom surface of each of the first and second trenches; and
forming a second fill material layer along the first fill material layer.

17. The method of claim 16, and further comprising planarizing the first fill material layer and the second fill material layer to a surface of the dielectric layer.

18. The method of claim 17, wherein the planarizing comprises an oxide chemical mechanical polishing step to the surface of the dielectric layer.

19. The method of claim 17, wherein the planarizing comprises:
an oxide chemical mechanical polishing step to a region away from the surface of the dielectric layer; and
a wet oxide etch, from the region away from the surface of the dielectric layer, to the surface of the dielectric layer.

20. The method of claim 16, wherein the fill material comprises silicon dioxide, exclusive of nitrogen.
